(19) United States
(12) Patent Application Publication
(10) Pub. No.: US 2015/0084005 A1
(43) Pub. Date: Mar. 26, 2015

(54) LEDS WITH IMPROVED LIGHT EXTRACTION

(71) Applicant: General Electric Company, Schenectady, NY (US)

(72) Inventors: Srinivas Prasad Sista, Niskayuna, NY (US); Jie Jerry Liu, Niskayuna, NY (US); Xiaolei Shi, Niskayuna, NY (US); Joseph John Shiang, Niskayuna, NY (US); Kevin Henry Janora, Schenectady, NY (US)

(73) Assignee: General Electric Company, Schenectady, NY (US)

(21) Appl. No.: 14/034,151

(22) Filed: Sep. 23, 2013

(51) Int. Cl. H01L 51/52

(52) U.S. Cl. CPC H01L 51/5268
USPC 257/40

(57) ABSTRACT

A light extraction structure that includes a composition of a base material and a scattering material disposed within the base material. The scattering material is a metal oxide, and the difference between the refractive indices of the base material and the scattering material is at least +/−0.05.

### BACKGROUND

In recent years, organic semiconductor devices have become more prevalent in technologies developed for lighting and display applications. Organic semiconductor devices are often a low cost, high performing alternative to traditional silicon semiconductor devices. One such organic semiconductor device is an organic light-emitting diode (OLED). An OLED is a device that contains organic materials that convert electrical energy into light.

Generally, OLEDs are fabricated by depositing thin films of organic semiconductor materials in between two conductive materials that act as electrodes. This organic material stack is then placed between two substrates, often made of glass, and plastic with moisture barriers, to hermetically seal the device from moisture and oxygen.

The two electrodes provide charge carriers, either electrons or holes, to the OLED. When an external voltage is applied, the opposing charge carriers recombine in the organic materials and, as a result, emit light. However much of the light produced by OLEDs is trapped within the device. For a typical OLED, only ˜20% light generated can escape from the substrate and optical losses can amount to up to eighty percent of the light emitted in the organic materials in an OLED. Typically, about thirty percent of the light is trapped within the substrates, and another thirty percent is trapped in the organic materials. This problem of high optical losses also occurs in traditional light emitting diodes (LED), as they share the same structure as OLEDs, with the exception of using inorganic semiconductor materials.

### BRIEF DESCRIPTION

Certain embodiments commensurate in scope with the originally claimed subject matter are summarized below. These embodiments are not intended to limit the scope of the claimed subject matter, but rather these embodiments are intended only to provide a brief summary of possible embodiments. Indeed, the present disclosure may encompass a variety of forms that may be similar to or different from the embodiments set forth below.

In one embodiment, a light extraction structure includes a base material and a scattering material dispersed within the base material. The base material and the scattering material have a first and second refractive index, respectively, and the difference between the two refractive indices is at least +/−0.05. The scattering material is a metal oxide. The base material is amorphous.

In another embodiment, a light extraction structure includes a first layer that includes a base material and a scattering material disposed within the base material. The light extraction structure also includes a planarization layer disposed directly over the first layer. The base material, scattering material, and planarization layer have a first, second, and third refractive index, respectively.

In yet another embodiment, a light emitting diode (LED) includes: a substrate, a light extraction structure disposed over the substrate, a transparent anode disposed over the light extraction structure, a plurality of layers of semiconductor materials disposed over the transparent anode, and a cathode disposed over the layers of semiconductor materials. The layers of semiconductor materials include: a hole injection layer, a hole transport layer disposed over the hole injection layer, a light emission layer disposed over the hole transport layer, and an electron transport layer disposed over the light emission layer. The light extraction structure includes a first layer that includes a base material and a scattering material disposed within the base material. The scattering material is a metal oxide. The base material is amorphous. The light extraction structure is configured to reduce the amount of total internal reflection that occurs within the semiconductor materials.

### BRIEF DESCRIPTION OF THE DRAWINGS

These and other features, aspects, and advantages of the present invention will become better understood when the following detailed description is read with reference to the accompanying drawings in which like characters represent like parts throughout the drawings, wherein:

FIG. 1 is a cross-sectional view of a conventional OLED;

FIG. 2 is a cross-sectional view of an OLED with a single layer light extraction structure, in accordance with one embodiment of the present approach;

FIG. 3 is a cross-sectional view of an OLED with a single layer light extraction structure, in accordance with another embodiment of the present approach;

FIG. 4 is a cross-section view of an OLED with a bi-layer light extraction structure, in accordance with one embodiment of the present approach;

FIG. 5 is a cross-sectional view of an OLED with a bi-layer light extraction structure, in accordance with another embodiment of the present approach;

FIG. 6 is a cross-sectional view of an OLED with a bi-layer light extraction structure, in accordance with another embodiment of the present approach;

FIG. 7 is a graph displaying the efficiency of OLEDs with and without a single layer light extraction structure;

FIG. 8 is a graph displaying the leakage current of an OLED, an OLED with a single layer light extraction structure, and an OLED with a bi-layer light extraction structure;

FIG. 9 is a graph displaying the efficiency of an OLED, an OLED with a single layer light extraction structure, and an OLED with a bi-layer light extraction structure; and

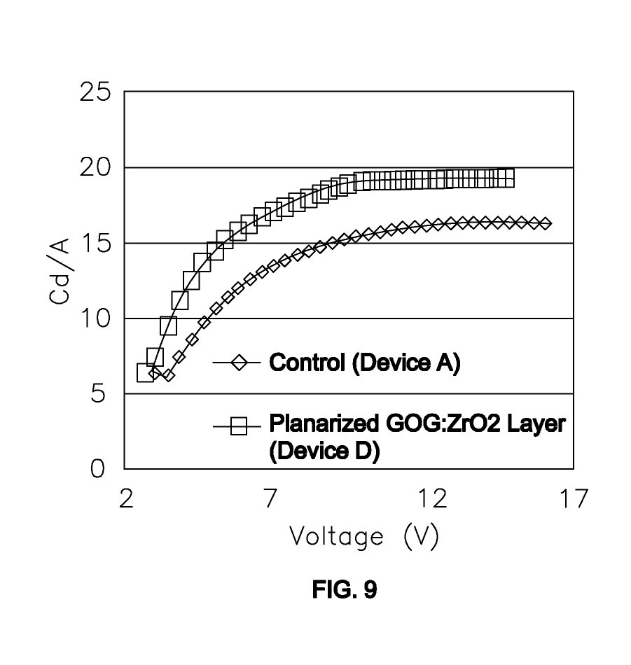

FIG. 10 is a graph displaying the surface profile of a portion of the bi-layer light extraction structure of FIG. 6, in accordance with an embodiment of the present approach.

### DETAILED DESCRIPTION

In the following specification and the claims which follow, reference will be made to a number of terms which shall be defined to have the following meanings. The singular forms “a”, “an”, and “the” include plural referents unless the context clearly dictates otherwise. The term “semiconductor materials” may refer to any material whose electron-hole recombination process results in optical emission. The term “organic materials” may refer to small molecular organic compounds, high molecular organic compounds, phosphorescent materials, or polymer organic compounds. As used herein, the term “disposed over” or “deposited over” refers to disposed or deposited directly on top of and in contact with, or disposed or deposited on top or but with intervening layers there between. The term “disposed directly over” or “deposited directly over” refers to disposed or deposited directly on top of and in contact with and with no intervening layers there between. It should be appreciated that the illustrated organic light emitting diodes (OLEDs) are merely provided as an example and, accordingly, that the embodiments described herein may be employed in any light emitting diode (LED).

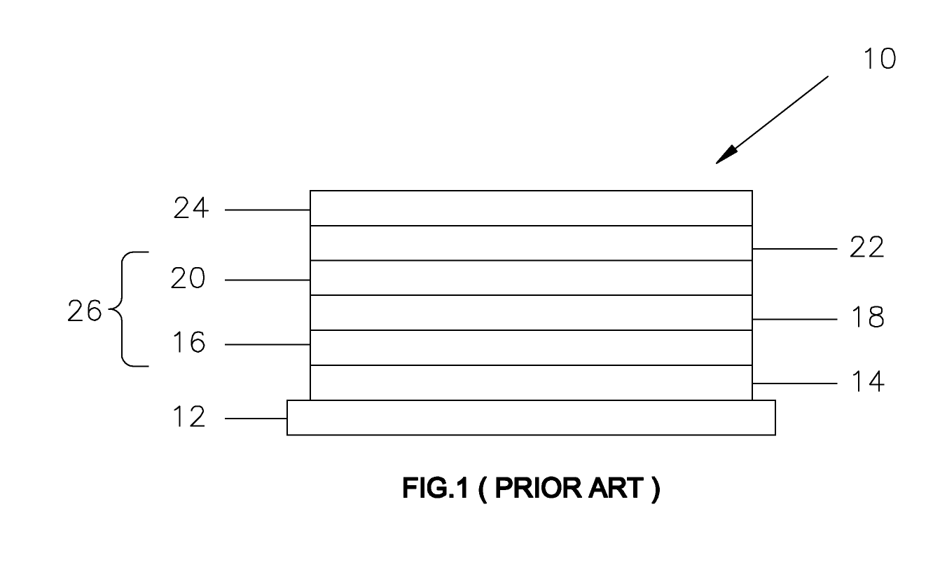

Referring now to FIG. 1, a conventional OLED 10 is an organic semiconductor device that emits light when connected to an external power supply. The conventional OLED 10, as shown, is a multi-layer dielectric stack including a substrate 12, an anode 14, a hole injection layer (HIL) 16, a hole transport layer (HTL) 18, a light emission layer (EML) 20, an electron transport layer (ETL) 22, and a cathode 24. Although it is not shown in FIG. 1, a second substrate 12 may be disposed over the cathode 24.

The substrate 12 is typically a glass or plastic material, and provides a hermetic seal for the conventional OLED 10 against moisture and oxygen. The anode 14 supplies holes to the HIL 16 and the cathode 24 supplies electrons to the ETL 22 during device operation. The cathode 24 may include an electron injection layer (EIL) or may be a separate layer deposited over the EIL. One or both of the anode 14 and the cathode 24 are made of thin transparent conducting films such as indium tin oxide. The conventional OLED 10 includes a transparent anode 14 through which light is emitted during device operation, as illustrated in FIG. 1. The HIL 16, the HTL 18, the EML 20, the ETL 22, and the EIL, if it is separate from the cathode 24, form the semiconductor materials 26 of the conventional OLED 10. As noted above, the semiconductor materials 26 are one or more materials whose electron-hole recombination process results in optical emission. In particular, the semiconductor materials 26 of the conventional OLED 10 are one or more organic materials that may be small molecular organic compounds, high molecular organic compounds, phosphorescent materials, or conjugated polymers, as described above. Accordingly, in traditional LEDs, the semiconductor materials 26 may be one or more inorganic materials such as GaAs or ZnSe.

When the conventional OLED 10 is connected to an external voltage source, the electrons and holes provided by the anode 14 and the cathode 24 recombine in the EML 20. This recombination process leads to an excess of energy in the form of photons. Although the emitted light is within the near-infrared, visible, or near-ultraviolet portions of the spectrum, the actual wavelength of the light is determined by the semiconductor materials 26, specifically the amount of energy left over after successful recombination.

However the direction in which the photons travel is uncontrolled in the conventional OLED 10 and in traditional LEDs, and so the amount of light which is emitted through the transparent anode 14 and the substrate 12 is only a fraction of the total light produced. Much of the light is trapped within the semiconductor materials 26 the transparent anode 14 as well as the substrate 12 due to total internal reflection (TIR). TIR is a phenomenon that occurs when light attempts to pass from one material with a refractive index a to a second material with a refractive index b, wherein refractive index b is less than refractive index a. If the light strikes the boundary between the two materials at some angle larger than or equal to a critical angle, then all of the light is reflected.

To reduce the amount of TIR within the semiconductor materials 26, one or more additional layers may be placed between the semiconductor materials 26 and the anode 14. The one or more additional layers may include a scattering material to change the direction in which the emitted light travels. The one or more additional layers may also have a refractive index such that the refractive index of the LED layers slowly decreases when moving from the semiconductor materials 26 to the anode 14. As a result, the one or more additional layers may reduce the difference between the refractive indices of two successive layers, which subsequently increases the value of the critical angle and reduces the amount of light that is reflected.

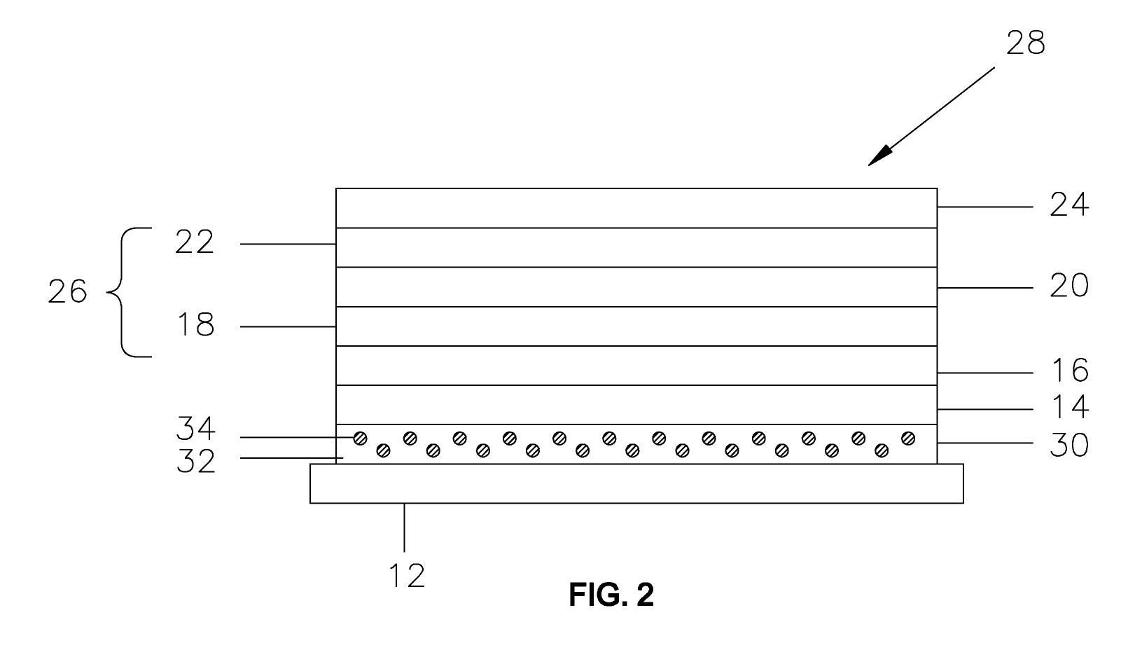

Turning now to FIG. 2, the OLED 28 with a single layer light extraction structure 30 is illustrated. The OLED 28 is similar in structure to the conventional OLED 10 regarding the substrate 12, the anode 14, the cathode 24, and the semiconductor materials 26. However, the OLED 28 includes a single layer light extraction structure 30 that is deposited between the anode 14 and the substrate 12, as shown in FIG. 2.

The single layer light extraction structure 30 may be a light scattering composition, including a base material 32 and a scattering material 34. The base material 32 may be a glass material or an organic binder that has a first refractive index that is high enough to match that of the semiconductor materials 26 in an LED. For example, the first refractive index is preferably at least 1.7 to match that of most semiconductor materials 26 used in OLEDs 28. Additionally, if the semiconductor materials 26 are one or more organic materials, then the base material 32 may need to have excellent solvent resistance properties to commonly used organic solvents, such as Toluene, Acetone, Isopropanol, and Chlorobenzene.

The scattering material 34 may be micron-size particles ranging in size from 0.2 μm to 10 μm, embedded in the base material 32. The scattering material 34 may be a crystalline metal oxide such as, but not limited to, ZrO₂, Al₂O₃, TiO₂, ZnO, HfO₂, and HfSiO₂. The scattering material 34 has a second refractive index, and the difference between the first refractive index and the second refractive index should be at least +/−0.05. The greater the difference between the first refractive index and the second refractive index, the more scattering will occur in the single layer light extraction structure 30.

It may be desirable to use a base material 32 with a first refractive index that is less than that of the semiconductor materials 26, due to reduced manufacturing costs, a wider variety of eligible materials, reduced weight, or any number of other criteria. For example, the base material 32 in the OLED 28 may be a spin-on-glass or polymer material with excellent solvent resistance properties to commonly used organic solvents, and with a first refractive index that is less than 1.7.

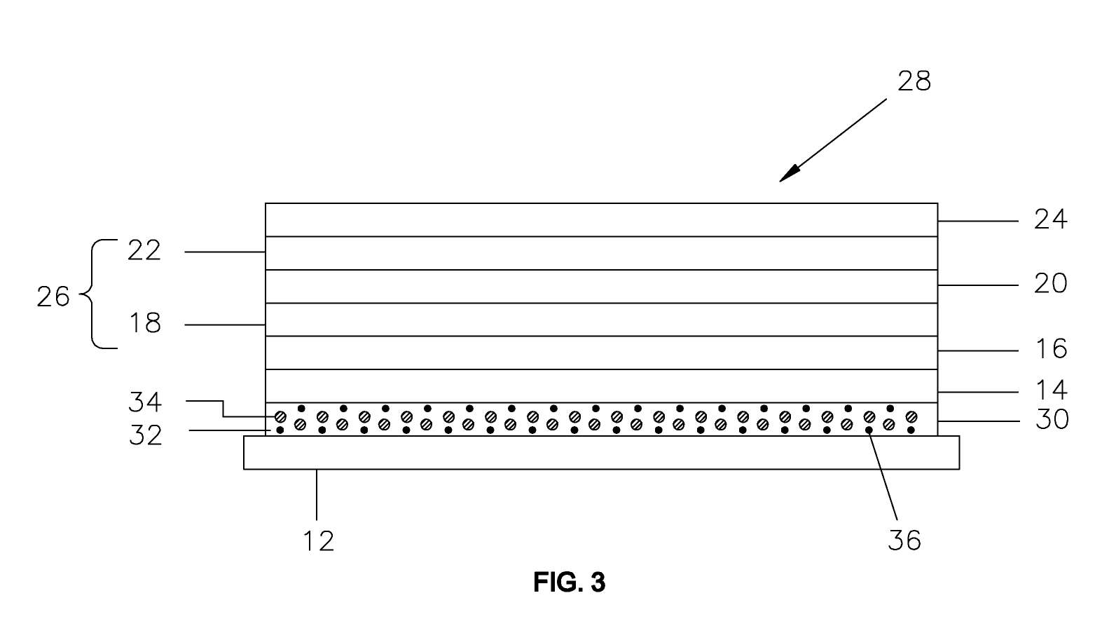

To raise the refractive index of the base material 32, nanoparticles 36 may be uniformly dispersed within the base material 32, as shown in FIG. 3. The nanoparticles 36 may be metal oxides such as ITO, TiO₂, ZnO, ZrO₂, and HfO₂. The nanoparticles 36 range in size from 2 nm to 20 nm such that they scatter a minimal amount of light compared to the scattering material 34. The nanoparticles 36 have a third refractive index. If the base material 32 is a spin-on-glass material, then the third refractive index should be at least the first refractive index+0.1. If the base material 32 is a polymer material, then the third refractive index should be at least the first refractive index+0.3.

While the single layer light extraction structure 30 does decrease the TIR and increase the light output of the OLED 28, the OLED 28 may exhibit a much higher amount of leakage current compared to the conventional OLED 10. This is because the single layer light extraction structure 30 may have many micron size defects due to fabrication. These defects lead to increased shorting and reduced yield of the OLED 28.

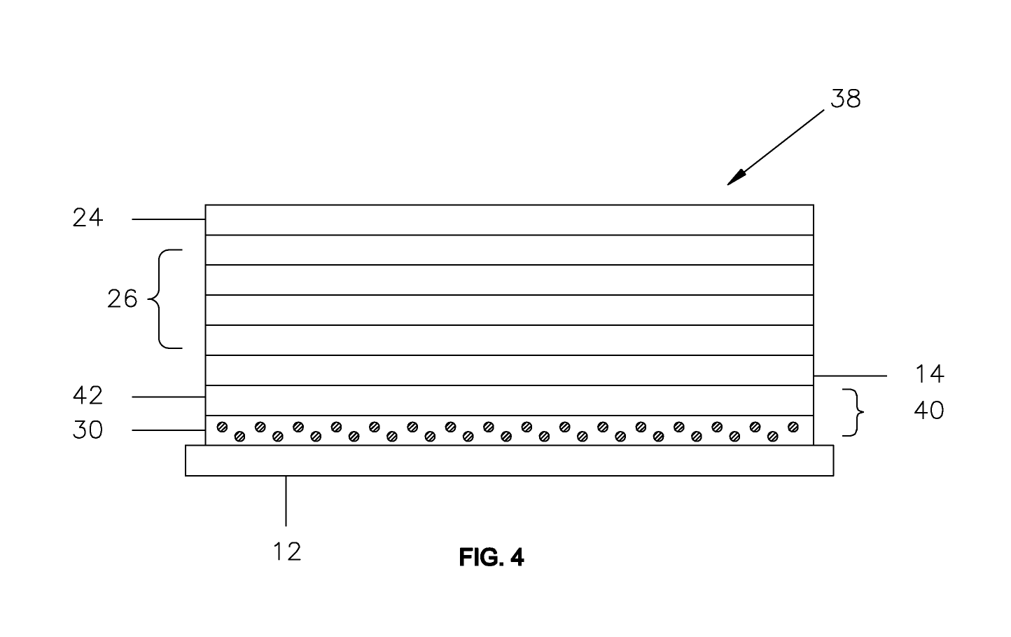

To reduce the amount of leakage current, an OLED 38 uses a bi-layer light extraction structure 40, as shown in FIG. 4. The bi-layer light extraction structure 40 is the single layer light extraction structure 30 with a planarization layer 42 deposited directly over it. The planarization layer 42 smoothes the rough surface of the single layer light extraction structure 30, reducing the amount of leakage current and subsequently increasing the yield of the OLED 38. The planarization layer 42 also simplifies the manufacturing process, as it provides a smooth surface over which the semiconductor materials 26 may be deposited.

In general, the planarization layer 42 should have a high refractive index, high transparency (at least 90%), and low haze (less than 5%, preferably less than 1%). If used in an OLED, it should also have excellent solvent resistance properties to commonly used organic solvents, similar to the single layer light extraction structure 30.

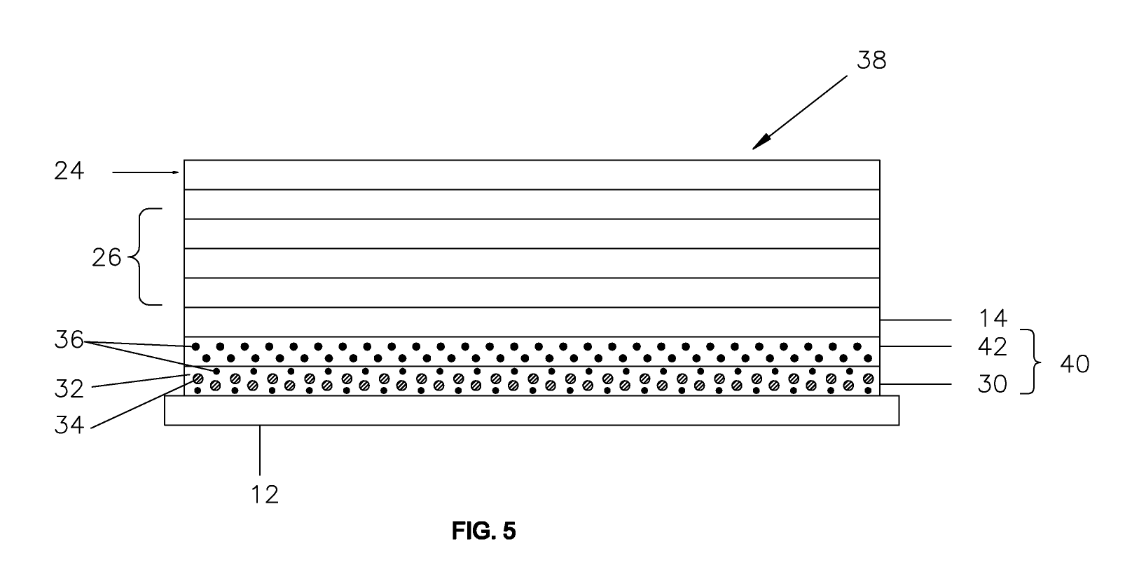

The planarization layer 42 may be a spin-on-glass material with a fourth refractive index that matches that of the semiconductor materials 26, as shown in FIG. 4. However, the planarization layer 42 may also be a spin-on-glass material or ultraviolet (UV) curable polymer or monomer with a fourth refractive index that is less than that of the semiconductor materials 26. If so, then the nanoparticles 36, with a third refractive index, may be added to the planarization layer 42 to increase the refractive index of the planarization layer 42, as shown in FIG. 5. The size of and type of materials used for the nanoparticles 36 is the same as listed for the single layer light extraction structure 30. If the planarization layer 42 is a spin-on-glass material, then the third refractive index should be at least the fourth refractive index+0.3. If the planarization layer 42 is a UV curable polymer or monomer, then the third refractive index should be at least the fourth refractive index+0.1.

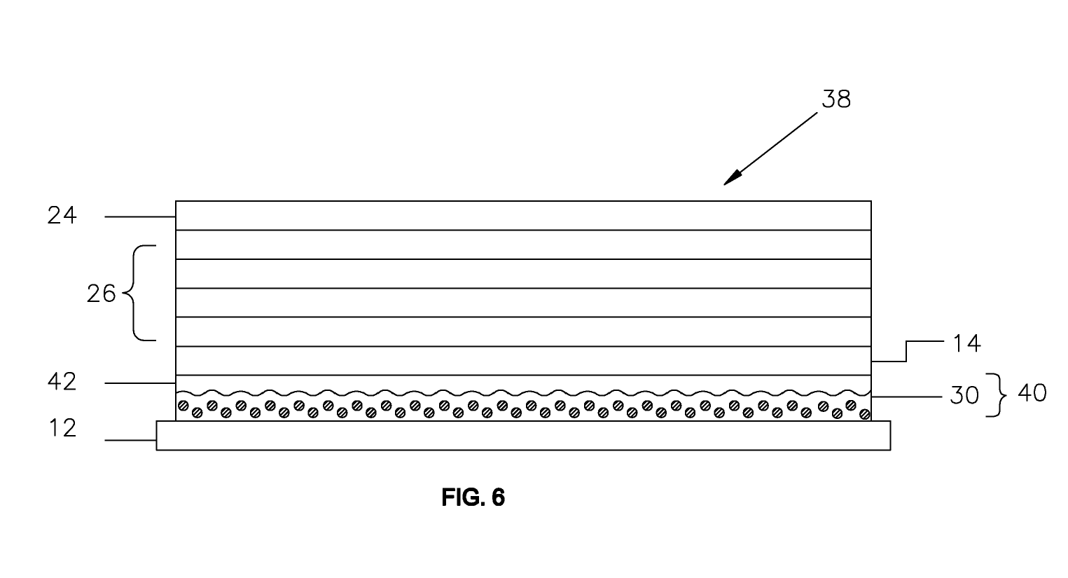

The OLED 38 may include a single layer light extraction structure 30 that is intentionally textured, as shown in FIG. 6. The single layer light extraction structure 30 is textured with micro lenses or micro cones with dimensions less than 10 p.m. The existence of peaks and troughs in the single layer light extraction structure 30, as opposed to a more uniform surface, may lead to additional scattering due to the variety of angles at which light may strike the surface. The textured single layer light extraction structure 30 may be manufactured in the same manner as one or more of the embodiments described above.

### Examples

### Manufacture of Glass Substrate with Scattering Layer

A solder glass slurry was prepared in a 60 ml plastic Nalgene bottle. 0.3291 g (1.5% of final mass) 1 micron zirconium (IV) oxide (Alfa stock No. 40140) was added to 21.63 g Schott 8465 solder glass (75% total solids) & 7.368 g Bush terpineol (25% liquid). The Schott 8465 solder glass were 5 micron particles (Schott's K5 grind) and used as received. The resulting mixture was hand mixed briefly with a stainless steel spatula and then milled to break up agglomerates that are noticeable as large chunks during tape casting. About twenty ¼″ diameter and five ½″ diameter cylindrical yttria-stabilized zirconia milling media were added to the slurry. The 1″×1″ or 3″×3″ soda-lime glass substrates were cleaned by rubbing them with a 2-propanol soaked cleanroom wipe and a 2-propanol rinse and then blow dried using a nitrogen gun.

Two layers of 50 microns thick Scotch tape were then applied on either side of the soda-lime glass substrates to create a gap of 100 microns. A small blob of the slurry was then applied at one end of the substrate. A razor or 2″×3″ microscope slide edge was dragged across the substrate at a 45° angle to create a 100 micron thick wet slurry film. The approximate speed of blade was ˜2 mm/sec. Any excess slurry was wiped off the edges and at the bottom to prevent the substrate from sticking to the stainless steel plate during firing.

The scotch tape was removed before drying the films in open air on a hot plate at 125° C. for 10 minutes. The dried substrate was then placed on an oxidized 321 stainless steel plate and covered with a stainless steel sheet placed 1 cm above the surface of the coated substrate or was placed in a stainless steel bag. The stainless steel plate was then inserted into a Lindberg type 51848 box furnace, which was heated to 450° C. at a rate of 100° C./min. After maintaining the temperature of the furnace at 450° C. for 10 minutes, the temperature was slowly increased from 450° C. to 550° C. at 5° C./min. The substrates were heated at 550° C. for 2 hours. To cool the substrates, the furnace was turned off and the substrates sat overnight in the furnace with the furnace door closed. After 24 hours at room temperature and humidity, the substrates were refired in the same furnace with a moderately slow increase of 5° C./min to a temperature of 650° C. and then held for 2 hours. Finally the substrates were again cooled down overnight with the furnace off.

Fabrication of OLEDs with and without a Single Layer Light Extraction Surface

OLEDs were fabricated on plain glass substrate that was used as control device (Device A) and with a single layer light extraction surface (Device B). We used solder glass layers with 1.5% concentration of 1 μm Zirconia particles (GOG:ZrO₂) as the single layer light extraction structure.

Next all the substrates were coated with ITO film by sputtering. Substrates were cleaned sequentially using detergent solution, DI Water, Acetone and Isopropanol. The substrates were then blown dry using a nitrogen gun and a ten minute UV ozone treatment. CH8000 was used as a hole injection material and was spin coated on cleaned substrates at 5000 rpm to achieve 50 nm thick films that were subsequently baked at 120° C. for 10 min in air. The parts were then transferred into an inert atmosphere to coat the subsequent organic layers. A hole transport layer was spin coated at 2500 rpm from 0.5 wt. % solution of TFB polymer in Toluene and was baked at 200° C. for 60 minutes. A thick emissive layer (200 nm) of a fluorescent green polymer (LEP1304) was obtained by spin coating at 1400 rpm from 2.0 wt. % solution in p-Xylene. The resulting films were baked at 135° C. for 15 minutes. In the final step the electron injection layer (NaF-38 Å) and the top metal contact (Al-1200 Å) were deposited using thermal vapor deposition at 10⁻⁶ torr deposition pressure.

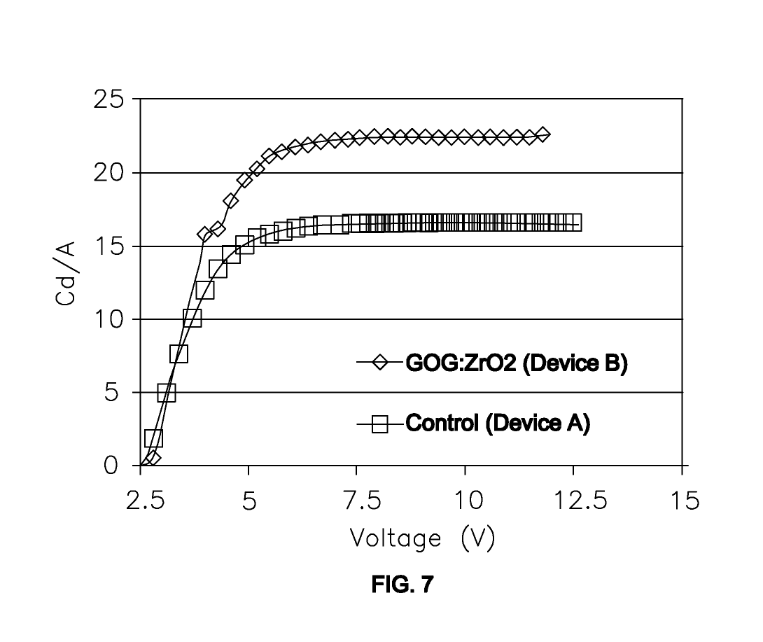

FIG. 7 shows the relative improvement in current efficiency of a green polymer OLED when GOG:ZrO₂ is used as a single layer light extraction structure. As shown below in Table 1, there is a thirty percent improvement in the external quantum efficiency (EQE) of the OLED with a single layer light extraction structure (device B) relative to a conventional OLED as the control (device A). This improvement in efficiency occurs because the single layer light extraction structure effectively extracts the device modes out into the air.

TABLE 1

| | At Brightness of 1000 Candela/m² | | | | | | |
|---|---|---|---|---|---|---|---|
| | | Lumens | External | | | | |
| | Drive | per | Quantum | | At Current Density | | |
| | Voltage | Watt | Efficiency | Watts/Watts | of 10 mA/cm² | | |
| ID | (DV) | (LPW) | (EQE) | (W/W) | DV | cd/m2 | LPW |
| Control (Device | 9.57 | 5.5 | 5.0% | 1.2% | 11.25 | 1651 | 4.6 |
| A) | | | | | | | |
| GOG:ZrO₂ | 8.39 | 8.4 | 6.6% | 1.7% | 10.73 | 2233 | 6.5 |
| (Device B) | | | | | | | |

Manufacture of Glass Substrate with Scattering and Planarization Layers

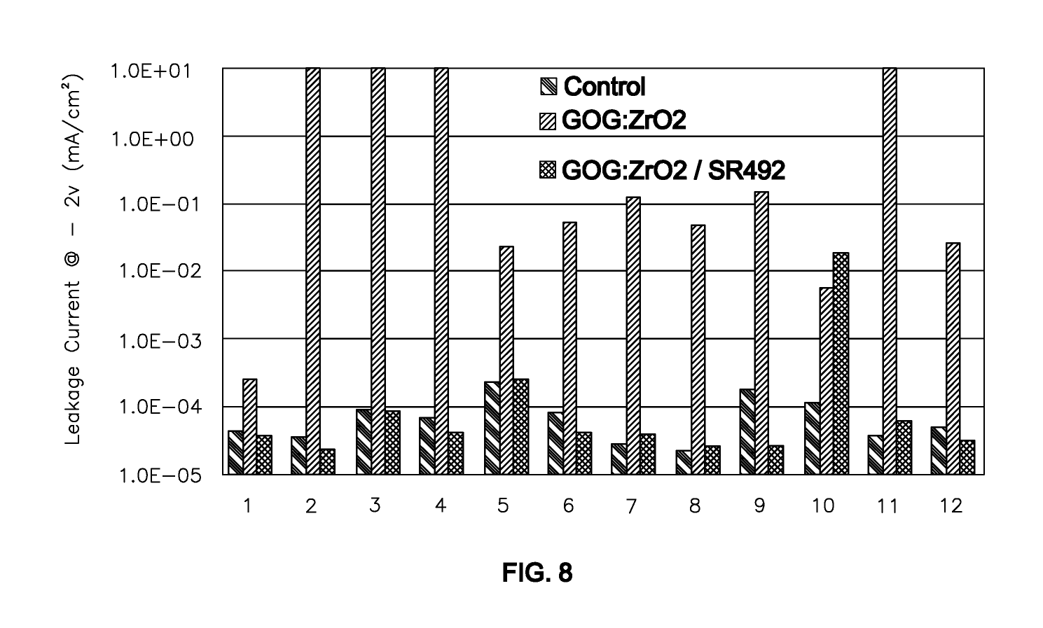

As a result of processing a GOG:ZrO₂ single layer light extraction surface on top of a soda lime glass substrate, the surface of the GOG:ZrO₂ layer has many micron size bumps. These micron size particle defects lead to shorting of OLEDs and hence reduce the yield of OLEDs. FIG. 8 shows the leakage current values of green polymer OLEDs fabricated on a plain glass substrate and a glass substrate with a GOG:ZrO₂ single layer light extraction structure. Several of the devices with a single layer light extraction structure have a high leakage current (>10⁻² mA/cm²).

In order to reduce the leakage current of OLEDs and hence improve the yield, a planarization layer was deposited over the rough surface of the GOG:ZrO₂ single layer light extraction structure. A 10 μm thick UV-curable acrylate layer was deposited over the GOG:ZrO₂ layer. Adding the SR492 planarization layer reduced the amount of leakage current, as shown in FIG. 8. The leakage current was reduced to less than 10⁻⁴ mA/cm², thereby improving the reliability of OLEDs.

Manufacture of Glass Substrate with Textured Scattering Layer

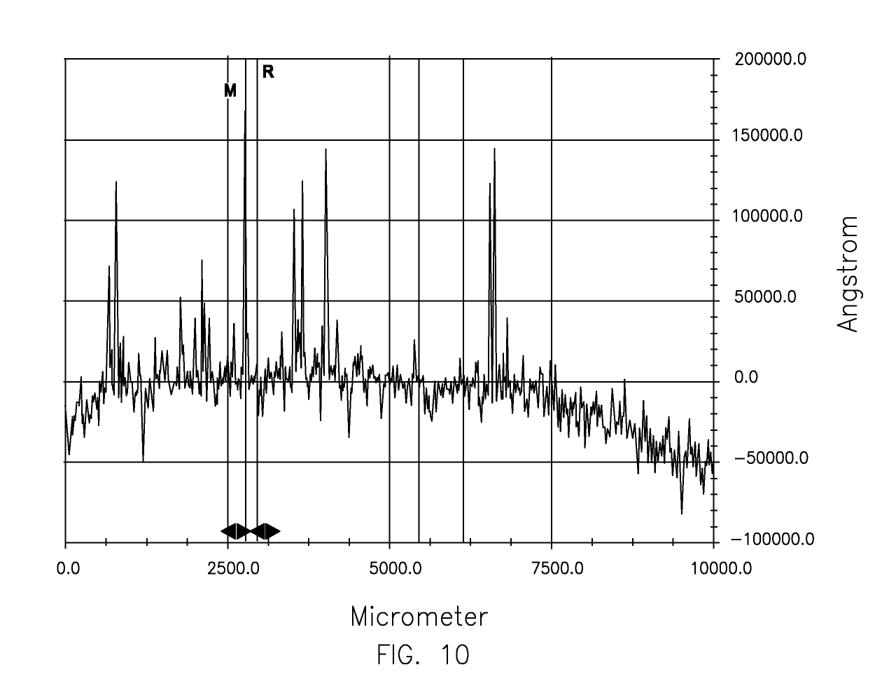

Grit blasting of soda-lime glass was done using a grit-blaster. 50 μm Mintec Quartz or 30-70 micron PTI Powder Technology's Arizona Test Dust was used as the grit-blasting media that was fed in at 5 grams/minute with 30 psi air at 25 SLM (42 SCFH) through a 64 mil ID alumina tube nozzle. The glass surface was typically kept at 5-10 mm from the nozzle tip. The nozzle was rastered across the surface roughening 1 cm² in about 10 seconds. Afterwards, a 10 minute ultrasonic in DI water was done to remove the residual glass dust. A brief toothbrush scrubbing followed by a DI rinse and a 80° C. hot plate drying resulted in cleaner grit-blasted surfaces. Surface roughness was measured using Tenco stylus profilometer and the surface profile is shown in FIG. 10. The root mean square (RMS) roughness of the grit blasted soda-lime microscope slide glass is around 1.0 μm and peak-to-trough value was about 4 μm.

One or more of the disclosed embodiments, alone or in combination, may provide one or more technical effects useful for designing and manufacturing LEDs used in display and lighting applications. Certain embodiments may allow for increased efficiency in LEDs. For example, the present single layer light extraction structure reduces the amount of light trapped within the semiconductor materials of an OLED due to TIR, compared to existing OLED technology. The present bi-layer light extraction structure not only reduces the amount of TIR, but also reduces the amount of leakage current to a level similar to, or better than, that of existing OLED technology. The technical effects and technical problems in the specification are exemplary and not limiting. It should be noted that the embodiments described in the specification may have other technical effects and can solve other technical problems.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A light extraction structure comprising:
a base material with a first refractive index; and
a scattering material with a second refractive index disposed within the base material, wherein the scattering material is a metal oxide;
wherein the difference between the first and second refractive indices is at least +/−0.05.

2. The light extraction structure of claim 1, wherein the light extraction structure comprises an organic light emitting diode (OLED).

3. The light extraction structure of claim 2, wherein the base material has solvent resistant properties to organic solvents.

4. The light extraction structure of claim 1, wherein the scattering material comprises particles ranging in size from 0.5 μm to 5 μm.

5. The light extraction structure of claim 1, wherein the base material is a glass material with a low melting point.

6. The light extraction structure of claim 1, wherein the base material is a polymer.

7. The light extraction structure of claim 1, comprising a semiconductor material, wherein the first refractive index of the base material matches a refractive index of the semiconductor material.

8. The light extraction structure of claim 1, comprising a semiconductor material, wherein the first refractive index of the base material is less than a refractive index of the semiconductor material.

9. The light extraction structure of claim 8, wherein nanoparticles with a third refractive index are dispersed uniformly within the base material.

10. The light extraction structure of claim 9, wherein the nanoparticles comprise a metal oxide and range in size from 2 nm to 20 nm.

11. The light extraction structure of claim 9, wherein the base material is a glass material, and the third refractive index of the nanoparticles is greater than the first refractive index of the base material by at least 0.1.

12. The light extraction structure of claim 9, wherein the base material is a polymer, and the third refractive index of the nanoparticles is greater than the first refractive index of the base material by at least 0.3.

13. The light extraction structure of claim 1, wherein the light extraction structure is planarized.

14. A light extraction structure comprising:
a first layer comprising a base material with a first refractive index and a scattering material with a second refractive index disposed within the base material; and
a planarization layer with a third refractive index disposed directly over the base material.

15. The light extraction structure of claim 14, wherein the scattering material comprises a metal oxide.

16. The light extraction structure of claim 14, wherein the light extraction structure comprises an OLED.

17. The light extraction structure of claim 16, wherein the base material and the planarization layer have solvent resistant properties to organic solvents.

18. The light extraction structure of claim 14, wherein the planarization layer has a transparency of at least 90%, a haze of less than 5%, or both.

19. The light extraction structure of claim 14, wherein the planarization layer is a glass material.

20. The light extraction structure of claim 14, wherein the planarization layer is an ultraviolet curable polymer or monomer.

21. The light extraction structure of claim 14, comprising a semiconductor material, wherein the third refractive index of the planarization layer matches that of the semiconductor material.

22. The light extraction structure of claim 14, comprising a semiconductor material, wherein the third refractive index of the planarization layer is less than that of the semiconductor material.

23. The light extraction structure of claim 22, wherein nanoparticles with a fourth refractive index are dispersed uniformly within the planarization layer.

24. The light extraction structure of claim 23, wherein the nanoparticles comprise a metal oxide and range in size from 2 nm to 20 nm.

25. The light extraction structure of claim 23, wherein the planarization layer is a glass material, and the fourth refractive index of the nanoparticles is greater than the third refractive index of the planarization layer by at least 0.3.

26. The light extraction structure of claim 23, wherein the planarization layer is a polymer or monomer, and the fourth refractive index of the nanoparticles is greater than the third refractive index of the planarization layer by at least 0.1.

27. The light extraction structure of claim 14, wherein the first layer is textured with micro lenses or micro cones with dimensions less than 10 μm.

28. A light emitting diode (LED) comprising:
a substrate;
a light extraction structure disposed directly over the substrate and comprising a first layer comprising a base material and a scattering material, wherein the scattering material comprises a metal oxide;
a first electrode disposed over the light extraction structure;
a plurality of layers of semiconductor materials disposed over the first electrode;
and
a second electrode disposed over the layers of semiconductor materials, wherein the light extraction structure is configured to reduce the amount of total internal reflection that occurs within the semiconductor materials.

29. The LED of claim 28, wherein the LED is an OLED.

30. The LED of claim 28, wherein the light extraction structure comprises a planarization layer.

31. The LED of claim 28, wherein the refractive indices of each successive layer decreases when moving from the layers of semiconductor materials to the first electrode.

32. The LED of claim 28, wherein the first electrode comprises a transparent anode and the second electrode comprises a cathode.

33. The LED of claim 28, wherein the first electrode comprises a transparent cathode and the second electrode comprises an anode.
